(19) United States
(12) Patent Application Publication
(10) Pub. No.: US 2025/0285901 A1
(43) Pub. Date: Sep. 11, 2025

(54) Methods And Systems For Robust, Automated Tuning Of Feedforward Motion Control Parameters

(71) Applicant: KLA Corporation, Milpitas, CA (US)

(72) Inventors: Phalguna Kumar Rachinayani, San Jose, CA (US); Dirk de Roover, Sherwood, OR (US); William Adams Clark, JR., San Jose, CA (US)

(21) Appl. No.: 19/066,788

(22) Filed: Feb. 28, 2025

Related U.S. Application Data
(60) Provisional application No. 63/561,746, filed on Mar. 6, 2024.

(51) Int. Cl. H01L 21/68; G03F 7/00

(52) U.S. Cl. CPC H01L 21/681; G03F 7/705; G03F 7/70725; G03F 7/70775

(57) ABSTRACT

Methods and systems for automatically tuning parameters of a feedforward based controller employed by a wafer positioning system in semiconductor processing equipment are described herein. One or more feedforward controller parameter values are selected to provide a desired motion performance at any location in the workspace of the wafer positioning system. The tuned feedforward controller operates in combination with a feedback controller to provide stable control of wafer motion. In one aspect, feedforward controller parameter values are selected to minimize a cost function including a simulated positioning performance associated with a first set of feedforward controller parameter values subtracted from a sum of a simulated positioning performance associated with an updated set of feedforward controller parameter values and a measured positioning performance associated with the first set of feedforward controller parameter values. In some examples, positioning performance is characterized by settling time.

### CROSS REFERENCE TO RELATED APPLICATION

The present application for patent claims priority under 35 U.S.C. § 119 from U.S. provisional patent application Ser. No. 63/561,746, filed Mar. 6, 2024, the subject matter of which is incorporated herein by reference in its entirety.

### TECHNICAL FIELD

The described embodiments relate to systems for specimen handling, and more particularly to methods and systems for improved specimen positioning performance.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography, among others, is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

A lithographic process, as introduced above, is performed to selectively remove portions of a resist material overlaying the surface of a wafer, thereby exposing underlying areas of the specimen on which the resist is formed for selective processing such as etching, material deposition, implantation, and the like. Therefore, in many instances, the performance of the lithography process largely determines the characteristics (e.g., dimensions) of the structures formed on the specimen. Consequently, the trend in lithography is to design systems and components (e.g., resist materials) that are capable of forming patterns having ever smaller dimensions. In particular, the resolution capability of the lithography tools is one primary driver of lithography research and development.

Measurement processes based on optical radiation, x-ray radiation, or electron based bombardment are used at various steps during a semiconductor manufacturing process to detect defects on wafers to promote higher yield. Optical metrology techniques offer the potential for high throughput without the risk of sample destruction. A number of optical metrology based techniques including scatterometry implementations and associated analysis algorithms to characterize device geometry have been described.

A wafer is positioned within a wafer processing tool (e.g., lithography tool, etch tool, inspection tool, metrology tool, etc.) by a multiple degree of freedom wafer positioning system. In many embodiments, a wafer positioning system includes two long stroke axes capable of moving the wafer in a plane approximately parallel with the top surface of the wafer. The two long stroke axes are able to move the wafer in the plane of such that any location on the wafer surface is addressable by a wafer processing subsystem, e.g., a metrology subsystem, an inspection subsystem, a lithography subsystem, an etch subsystem, a deposition subsystem, etc.

Typically, the position of the wafer within a wafer processing system is maintained by an active controller that calculates control signals based on feedback, e.g., position feedback, velocity feedback, etc. Feedback control signals are driven by errors calculated as the difference between measured motion variables and desired values of those motion variables, e.g., difference between the measured position of the wafer and the desired position of the wafer. Feedback control enables tracking of motion command signals, rejection of disturbance forces, and stable interaction between forces generated by multiple axes of a multiple degree of freedom wafer positioning system.

Unfortunately, the performance of a wafer positioning system controlled based on feedback signals alone has some limitations. A feedback control scheme is by definition reactive in nature because the controller is driven by errors. The errors must first be measured and then compensated by applying corrective force to the motion system. These actions take time, and thus limit tracking performance. Furthermore, the ability of a feedback control system to react quickly is limited by a number of practical physical considerations. For example, the finite stiffness of mechanical structures limits the achievable bandwidth of a stable and robust feedback controller. This, in turn, limits how quickly and effectively, a feedback based controller is able to track motion commands. Although, additional control elements such as input shaping and notch filters help to reduce the sensitivity of feedback controllers to structural dynamics, performance gains are limited and often come at a cost of decreased robustness.

In some motion control systems, feedforward control is implemented, in addition to feedback control, to improve motion performance beyond the limitations imposed by feedback based control. A feedforward based control element calculates control signals based on knowledge of the desired motion trajectory, e.g., velocity feedforward, acceleration feedforward, jerk feedforward, etc. Feedforward control signals are driven by anticipated forces required to achieve a desired motion trajectory. Feedforward control is by nature proactive because feedforward control signals are driven by the desired motion trajectory, which is available instantaneously. Thus, control action derived from feedforward based signals is implemented instantaneously on the time scale of physical stage motion.

Feedforward control has the potential to improve tracking of motion command signals, minimize interaction forces between multiple axes of a multiple degree of freedom wafer positioning system, etc. However, to effectively realize the benefits of feedforward based control, precise system knowledge is required.

Traditionally, manual tuning of feedforward parameters is achieved based on precise system identification and trial-and-error techniques. Very often, the feedforward control parameters determined for one instance of a wafer positioning system are not effective when applied to another instance of the same wafer positioning system. Mechanical variations among different instances of a wafer positioning system are often large enough that a single set of feedforward control parameters will not achieve a desired motion performance across all instances of the wafer positioning system. As a consequence, each instance of a wafer positioning system must be individually tuned to guarantee acceptable motion performance.

In addition, feedforward control parameters must be selected such that the desired motion performance is achieved at all positions within the workspace of the multiple degree of freedom wafer positioning system. This compounds the tuning effort. First, system identification must be performed throughout the workspace. Second, a set of feedforward control parameters must be manually tuned to meet the desired motion performance requirements at all positions within the workspace. Often, the set of feedforward control parameters determined manually are not robust to variations in system behavior.

In a production setting, the effort required to manually tune feedforward control parameters of wafer positioning systems is limiting. Significant amounts of time are required to tune each system, the results are not as robust as desired, and extensive expertise and knowledge of both the system and controller tuning process is required. Improved methods and systems for tuning feedforward based controllers employed by wafer positioning systems in semiconductor processing equipment are desired.

### SUMMARY

Methods and systems for automatically tuning parameters of a feedforward based controller employed by a wafer positioning system in semiconductor processing equipment are described herein. Parameter values of a feedforward controller are selected to provide a desired motion performance at any location in the workspace of the wafer positioning system. The tuned feedforward controller operates in combination with a feedback controller to provide stable control of wafer motion in semiconductor processing equipment.

In some embodiments, a motion controller includes both a feedback controller and a feedforward controller. Typically, the feedback control element operates on motion errors, i.e., the difference between a desired motion and the actual, measured motion. The feedback control element generates motion commands based on the motion errors. In contrast, a feedforward control element generates motion commands based on the desired motion, directly. The motion commands generated by the feedback and feedforward control elements are communicated to a positioning subsystem. In response, forces/torques are generated by actuators of the wafer positioning system in response to the motion commands.

In some embodiments, a feedforward controller generates control signals from one or more motion parameters, e.g., position, velocity, acceleration, jerk, etc. In general, a feedforward controller may be configured to generate motion control signals from any number of motion parameters, including higher order derivatives of position.

In one aspect, parameters of a feedforward based controller employed by a wafer positioning system are automatically tuned. Values of parameters of a feedforward based controller are selected to minimize a cost function including a simulated positioning performance during a predetermined movement based on a first set of values of the feedforward control parameters subtracted from a sum of a simulated positioning performance during the predetermined movement based on an updated set of values of the feedforward control parameters and a measured positioning performance during the predetermined movement based on the first set of values of the feedforward control parameters. The number of feedforward parameters undergoing optimization can be one or more.

The inventors have discovered that the difference between simulated positioning performance at two different sets of values of feedforward control parameters and the difference between actual positioning performance at the same two different sets of values of the feedforward control parameters match very closely. Thus, the simulated positioning performance at both initial and updated sets of values of feedforward control parameters and the actual positioning performance at the initial set of values accurately estimates the actual positioning performance at the updated set of values. Hence, a minimization of the aforementioned cost function is performed to arrive at an updated set of values of feedforward parameters that achieves a desired motion performance.

In some examples, positioning performance is characterized by settling time, i.e., the time required for the position of a wafer to settle to the desired position within specification after the nominal movement is complete.

In some embodiments, the feedforward control parameters undergoing optimization are associated with a single input, single output controller configured to control one degree of freedom of a wafer positioning system.

In some embodiments, the feedforward control parameters undergoing optimization are associated with a multi-input, multi-output controller configured to control two or more degrees of freedom of a wafer positioning system.

In a further aspect, optimization of feedforward control parameters is associated with actual motion performance and simulated motion performance at multiple points in the workspace of wafer positioning system. In this manner, the optimized feedforward control parameter values ensure desired motion performance at different points in the workspace of the wafer positioning system.

The foregoing is a summary and thus contains, by necessity, simplifications, generalizations and omissions of detail. Consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a measurement system including a wafer positioning system configured to automatically tune feedforward controller parameter values associated with a feedforward controller employed to control motion of the wafer positioning system as described herein.

FIG. 2 is a diagram illustrative of a control scheme for controlling the motion of a wafer positioning system of a semiconductor measurement system in one embodiment.

FIG. 3 is a diagram illustrative of a feedforward controller for generating feedforward command signals in one embodiment.

FIG. 4A is a plot illustrative of an exemplary desired position trajectory associated with a displacement of approximately 120 millimeters.

FIG. 4B is a plot illustrative of an exemplary desired velocity trajectory associated with the desired position trajectory depicted in FIG. 4A.

FIG. 4C is a plot illustrative of an exemplary desired acceleration trajectory associated with the desired position trajectory depicted in FIG. 4A.

FIG. 4D is a plot illustrative of an exemplary desired jerk trajectory associated with the desired position trajectory depicted in FIG. 4A.

FIG. 5 is a simplified diagram of a top view of a workspace of a wafer positioning system.

FIG. 6 is a plot illustrative of position error as a function of time during a move and settle wafer stage movement from a location in the workspace of a wafer positioning system.

FIG. 7 illustrates a flowchart of an exemplary method useful for automatically tuning feedforward motion control parameter values in at least one novel aspect.

### DETAILED DESCRIPTION

Reference will now be made in detail to background examples and some embodiments of the invention, examples of which are illustrated in the accompanying drawings.

Methods and systems for automatically tuning parameters of a feedforward based controller employed by a wafer positioning system in semiconductor processing equipment are described herein. Parameter values of a feedforward controller are selected to provide a desired motion performance at any location in the workspace of the wafer positioning system. The tuned feedforward controller operates in combination with a feedback controller to provide stable control of wafer position in semiconductor processing equipment.

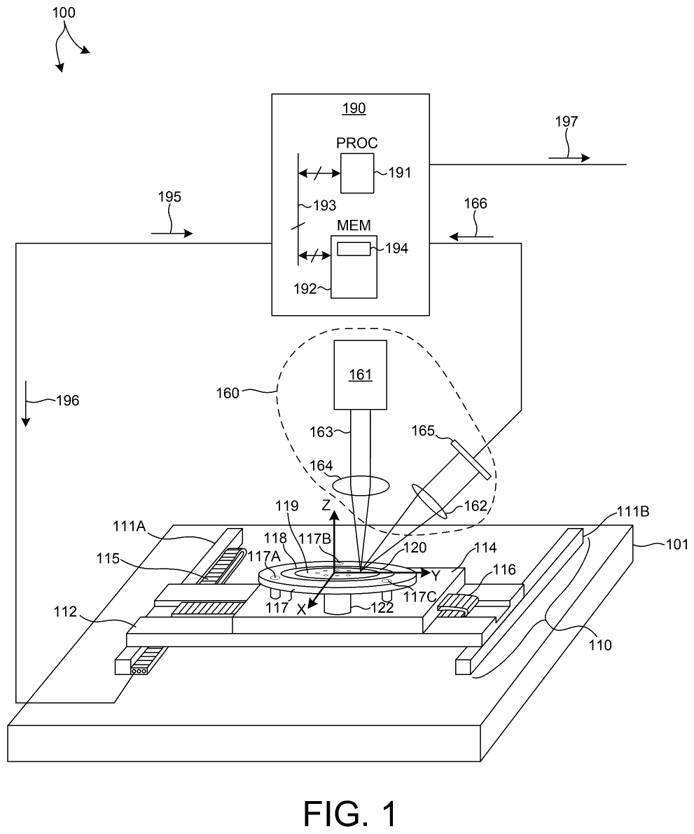

FIG. 1 is a diagram illustrative of a measurement system 100 including a machine frame 101, a wafer positioning system 110, a computing system 190, and a semiconductor measurement subsystem 160. As depicted in FIG. 1, wafer positioning system 110 is mechanically coupled to machine frame 101. Wafer positioning system 110 includes multiple motion stages that operate in coordination to move wafer 119 with respect to machine frame 101 in six degrees of freedom. Although wafer positioning system 110 is described herein as a six degree of freedom positioning system, in general, any wafer positioning system employed to locate a wafer in at least one degree of freedom is contemplated within the scope of this patent document.

As depicted in FIG. 1, wafer positioning system 110 includes a long stroke base stage including base reference structures 111A and 111B and X-frame 112. Base reference structures 111A and 111B are mechanically coupled to machine frame 110. X-frame 112 is mechanically constrained by bearing elements (not shown) to move with respect to base reference structures 111A and 111B in one degree of freedom that is approximately aligned with the X-direction depicted in FIG. 1. A base stage drive mechanism (not shown) generates drive forces to move X-frame 112 with respect to base reference structures 111A and 111B.

Wafer positioning system 110 also includes a long stroke intermediate stage including Y-frame 114 moveable with respect to X-frame 112. Y-frame 114 is mechanically constrained by bearing elements (not shown) to move with respect to X-frame 112 in one degree of freedom that is approximately aligned with the Y-direction depicted in FIG. 1. An intermediate stage drive mechanism (not shown) generates drive forces to move Y-frame 114 with respect to X-frame 112.

By way of non-limiting example, bearing elements of the base and intermediate stages may include mechanical linear bearings, linear air bearings, linear magnetic bearings, etc. In general, any suitable linear bearing arrangement may be contemplated within the scope of this patent document.

By way of non-limiting example, base stage and intermediate stage drive mechanisms may include a linear motor, a rotary motor and ball spindle, a rotary motor and belt drive, etc. In general, any suitable stage drive mechanism may be contemplated within the scope of this patent document. The base stage and intermediate stage are long stroke motion stages, e.g., total stroke of more than 100 millimeters.

Wafer positioning system 110 also includes a tip/tilt/Z stage including tip/tilt/Z stage 117 moveable with respect to Y-frame 114. Tip/tilt/Z stage 117 includes three linear actuators 117A-C configured to independently move tip/tilt/Z stage 117 linearly with respect to intermediate stage 114 in the Z-direction and rotate tip/tilt/stage 117 about the X and Y axes. Tip/tilt/Z stage 117 is a short stroke motion stage, e.g., total stroke of actuators 117A-C is less than 10 millimeters. By way of non-limiting example, linear actuators 117A-C may include a piezoelectric linear motor, a Lorentz coil motor, etc. In general, any suitable stage drive mechanism may be contemplated within the scope of this patent document.

Wafer positioning system 110 also includes a rotary stage including wafer chuck 120 constrained to rotate with respect to tip/tilt/Z stage 117. A rotary bearing (not shown) is configured to constrain the movement of wafer chuck 120 with respect to tip/tilt/Z stage 117 to rotation about the Z-axis. By way of non-limiting example, bearing elements of the rotary stage may include mechanical bearings, air bearings, magnetic bearings, etc. In general, any suitable rotary bearing arrangement may be contemplated within the scope of this patent document.

A rotary motor assembly 118 is configured to provide rotational torque to rotate wafer chuck 120 with respect to tip/tilt/Z stage 117 about the Z-axis. By way of non-limiting example, rotary motor assembly 118 may include a rotary motor and belt drive arrangement, a direct drive electric motor having rotor and stator elements mounted to the wafer chuck 120 and tip/tilt/Z stage 117, respectively, or vice-versa, etc. In general, any suitable rotary drive arrangement may be contemplated within the scope of this patent document.

Wafer 119 is clamped on the top surface of wafer chuck 120. In this manner, wafer positioning system 110 is configured to move wafer 119 in six degrees of freedom: linear motion aligned with the X, Y, and Z axes, which are orthogonal to one another, and rotational motion about the X, Y, and Z axes.

As depicted in FIG. 1, wafer positioning system 110 includes a dynamic cable system including dynamic cable 115 coupled to machine frame 101 and X-frame 112 and dynamic cable 116 coupled to X-frame 112 and Y-frame 114. Dynamic cable 115 provides routing for electrical wiring, positively pressurized air conduits, negatively pressurized air conduits, etc., between machine frame 101 and X-frame 112. Dynamic cable 116 provides routing for electrical wiring, positively pressurized air conduits, negatively pressurized air conduits, etc., between X-frame 112 and Y-frame 114. In the embodiment depicted in FIG. 1, negatively pressurized air 123 is routed from machine frame 101 through dynamic cable 115, through X-frame 112, through dynamic cable 116, through Y-frame 114, through vacuum feedthrough 122 to wafer chuck 120. In this manner, vacuum is provided from machine frame 101 to wafer chuck 120 to maintain wafer 119 clamped onto the top surface of wafer chuck 120.

Computing system 190 receives signals 195 indicative of motion of wafer 119 with respect to machine frame 101, e.g., position, velocity, acceleration, or any combination thereof. Based on signals 195 computing system 190 determines control command signals 196 communicated to one or more stages of wafer positioning system 110. In response, wafer positioning system 110 generates drive forces/torques that cause motion of wafer 119 relative to machine frame 101. In this manner, computing system 190 controls the motion of wafer 119 with respect to machine frame 101.

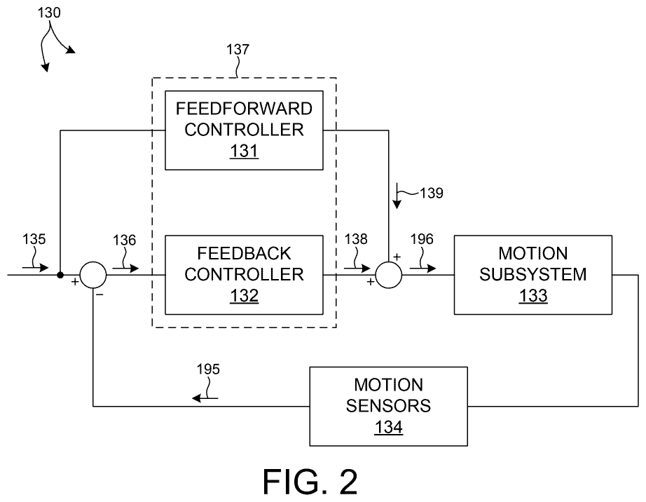

FIG. 2 is a diagram illustrative of a control scheme 130 for controlling the motion of a wafer positioning system of a semiconductor measurement system in one embodiment. Control scheme 130 includes a controller 137, a motion subsystem 133, and motion sensors 134. In one example, controller 137 is implemented by computing system 190 depicted in FIG. 1. In this example, motion subsystem 133 is implemented by the drive and mechanical elements of wafer positioning system 110 depicted in FIG. 1, e.g., electrical drive components, such as amplifiers and motors, and mechanical components such as frames, bearings, cabling, etc. Also in this example motion sensors 134 are implement by the motion sensors embedded in wafer positioning system 110, e.g., encoders, interferometers, inductive probes, capacitive probes, etc., employed to measure movements of wafer chuck 120 with respect to machine frame 101.

As depicted in FIG. 2, controller 137 includes both a feedback control element 132 and a feedforward control element 131. In one example, computing system 190 determines a motion error signal 136 as the difference between a desired motion command signal 135 and motion signals 195 indicative of the current state of motion of wafer 119 with respect to machine frame 101. The motion error signal 136 is provided as input to feedback controller 132. Computing system 190 implementing feedback controller 132 computes feedback command signals 138 based on the motion error signal 136. In addition, desired motion command signal 135 is provided as input to feedforward controller 131. Computing system 190 implementing feedforward controller 131 computes feedforward command signals 139 based on the desired motion command signal 135. Computing system 190 determines control command signals 196 as the sum of feedback command signals 138 and feedforward command signals 139. The control command signals 196 are communicated to wafer positioning subsystem 110. In response, forces/torques are generated by actuators of wafer positioning subsystem 110 that cause motion of wafer 119 with respect to machine frame 101. The motion is measured by motion sensors 134. Motion signals 195 indicative of the current state of motion of wafer 119 with respect to machine frame 101 are communicated to computing system 190 for another iteration of the control loop.

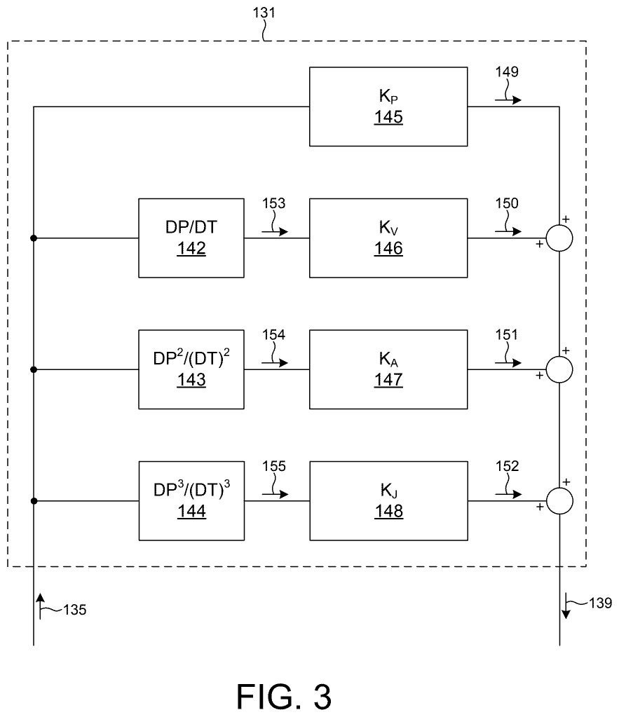

FIG. 3 is a diagram illustrative of a feedforward controller 131 for generating feedforward command signals 139 in one embodiment. As depicted in FIG. 3, feedforward controller 131 generates control signals from several motion parameters including position, velocity, acceleration, and jerk. In general, feedforward controller 131 may be configured to generate motion control signals from any number of motion parameters, including higher order derivatives of position.

As depicted in FIG. 3, desired position trajectory 135 is communicated to first order differentiation block 142. In one example, computing system 190 determines a first order derivative of desired position trajectory 135 with respect to time to generate a desired velocity trajectory 153. Similarly, desired position trajectory 135 is communicated to second order differentiation block 143. In one example, computing system 190 determines a second order derivative of desired position trajectory 135 with respect to time to generate a desired acceleration trajectory 154. Similarly, desired position trajectory 135 is communicated to third order differentiation block 144. In one example, computing system 190 determines a third order derivative of desired position trajectory 135 with respect to time to generate a desired jerk trajectory 155.

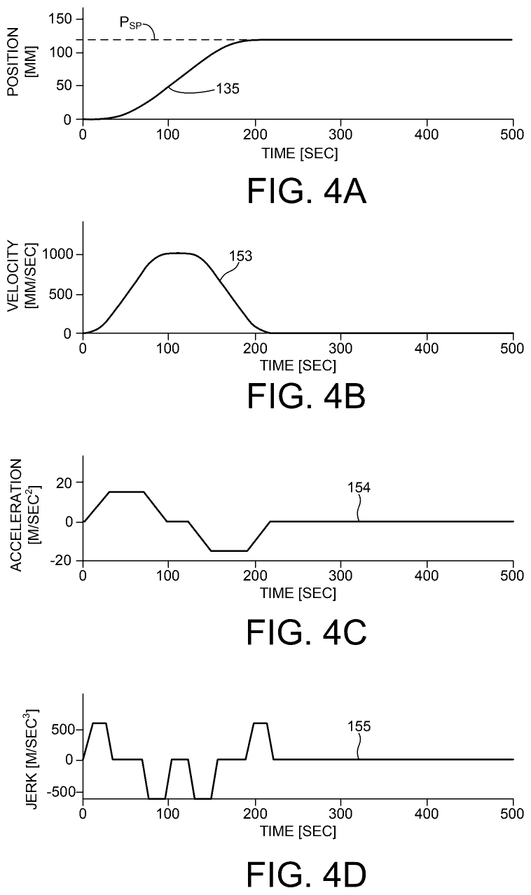

FIG. 4A is a plot illustrative of an exemplary desired position trajectory 135 for a displacement of approximately 120 millimeters. FIG. 4B is a plot illustrative of an exemplary desired velocity trajectory 153 associated with desired position trajectory 135. FIG. 4C is a plot illustrative of an exemplary desired acceleration trajectory 154 associated with desired position trajectory 135. FIG. 4D is a plot illustrative of an exemplary desired jerk trajectory 155 associated with desired position trajectory 135.

As depicted in FIG. 3, desired motion command signal 135 includes a desired position trajectory for a displacement of wafer 119 from one position to another. Desired motion command signal 135 is provided directly to position feedforward control element 145. Position feedforward control element 145 includes a position feedforward control parameter, K_{P}. In one example, computing system 190 determines position feedforward command signal 149 as the desired position command signal 135 multiplied by position feedforward control parameter, K_{P}.

Similarly, desired velocity trajectory 153 is provided directly to velocity feedforward control element 146. Velocity feedforward control element 146 includes a velocity feedforward control parameter, K_{V}. In one example, computing system 190 determines velocity feedforward command signal 150 as the desired velocity trajectory 153 multiplied by velocity feedforward control parameter, K_{V}.

Similarly, desired acceleration trajectory 154 is provided directly to acceleration feedforward control element 147. Acceleration feedforward control element 147 includes an acceleration feedforward control parameter, K_{A}. In one example, computing system 190 determines acceleration feedforward command signal 151 as the desired acceleration trajectory 154 multiplied by acceleration feedforward control parameter, K_{A}.

Similarly, desired jerk trajectory 155 is provided directly to jerk feedforward control element 148. Jerk feedforward control element 148 includes a jerk feedforward control parameter, K_{J}. In one example, computing system 190 determines jerk feedforward command signal 152 as the desired jerk trajectory 155 multiplied by jerk feedforward control parameter, K_{J}.

In one aspect, parameters of a feedforward based controller employed by a wafer positioning system are automatically tuned. Parameter values of a feedforward controller are selected to provide a desired motion performance at any location in the workspace of the wafer positioning system. The tuned feedforward controller operates in combination with a feedback controller to provide stable control of wafer position in semiconductor processing equipment.

Values of parameters of a feedforward based controller, e.g., Kₚ, Kᵥ, Kₐ, and K_{J} depicted in FIG. 3, are selected to minimize a cost function including a simulated positioning performance during a predetermined movement based on a first set of values of the feedforward control parameters subtracted from a sum of a simulated positioning performance during the predetermined movement based on an updated set of values of the feedforward control parameters and a measured positioning performance during the predetermined movement based on the first set of values of the feedforward control parameters. Equation (1) illustrates the cost function to be minimized, where ^{s}Y(x) is the simulated positioning performance based on the updated set of values of the feedforward control parameters, ^{S}Y(x₀) is the simulated positioning performance based on the first set of values of the feedforward control parameters, and ^{M}Y(x₀) is the measured positioning performance based on the first set of values of the feedforward control parameters.

$$min \vert {}^{S} Y ( x ) - {}^{S} Y ( {x}_{0} ) + {}^{M} Y ( {x}_{0} ) \vert \qquad ( 1 )$$

Experience has shown that it is extremely difficult to build a simulation model of positioning performance that matches actual measured positioning performance when high positioning performance is required. Thus, it is difficult to use a simulated model of positioning performance to directly predict values of feedforward control parameters that deliver high positioning performance in actual practice.

However, the inventors have discovered that the difference between simulated positioning performance at two different sets of values of feedforward control parameters and the difference between actual positioning performance at the same two different sets of values of the feedforward control parameters match very closely as illustrated by the relationship of Equation (2).

$$\vert {}^{M} Y ( x ) - {}^{M} Y ( {x}_{0} ) \vert \approx \vert {}^{S} Y ( x ) - {}^{S} Y ( {x}_{0} ) \vert \qquad ( 2 )$$

In some examples, positioning performance is characterized by settling time, i.e., the time required for the position of wafer 119 to settle to the desired position within specification after the nominal movement is complete. In one example, Y, is the settling time. It is desirable to select an updated set of feedforward parameter values, x, that minimize the actual settling time evaluated at those parameter values as illustrated by Equation (3).

$$min {\vert}^{M} Y ( x ) \vert \qquad ( 3 )$$

Based on the observation described with reference to Equation (2), the minimization described by Equation (3) is recast as the minimization illustrated by Equation (1). In some examples, the desired performance is achieved in one step. In some other examples, the minimization is performed iteratively to arrive at an updated set of values of the feedforward parameters that achieves the desired motion performance.

As described hereinbefore, the number of feedforward parameters undergoing optimization can be one or more. In some examples, a feedforward controller is characterized by a single feedforward parameter, e.g., acceleration feedforward, K_{A}. In these examples, only the single feedforward parameter value is optimized. In other examples, a feedforward controller is characterized by more than one feedforward parameter, e.g., feedforward controller 131 depicted in FIG. 3. In these examples, multiple feedforward parameter values are optimized.

In some embodiments, the feedforward control parameters undergoing optimization is associated with a single input, single output controller configured to control one degree of freedom of a single degree of freedom or multi-degree of freedom wafer positioning system. In the embodiment described with reference to FIG. 1, wafer positioning system 110 is a six degree of freedom positioning system. In this embodiment, six different stage motions are coordinated to move wafer 119 arbitrarily in the six degree of freedom workspace of the wafer positioning system. In some embodiments, each of the six different stage motions are independently controlled by corresponding single input, single output controllers. In one example, motion controller 137 is characterized by a set of feedback and feedforward parameter values employed to control the movements of the X-stage of wafer positioning system 110. In this same example, another instance of motion controller 137 is characterized by a different set of feedback and feedforward parameter values employed to control the movements of the Y-stage of wafer positioning system 110.

In some embodiments, the feedforward control parameters undergoing optimization is associated with a multi-input, multi-output controller configured to control two or more degrees of freedom of a multi-degree of freedom specimen positioning system. In one example, motion controller 137 is a multi-input, multi-output controller characterized by a set of feedback and feedforward parameter values employed to control the movements of the X-stage and Y-stage of wafer positioning system 110 in combination.

In a further aspect, optimization of feedforward control parameters is associated with actual motion performance and simulated motion performance at multiple points in the workspace of a specimen positioning system. In this manner, the optimized feedforward control parameter values ensure desired motion performance at different points in the workspace of the specimen positioning system. Thus, the optimized feedforward control parameter values ensure robust motion control over the entire workspace of the specimen positioning system.

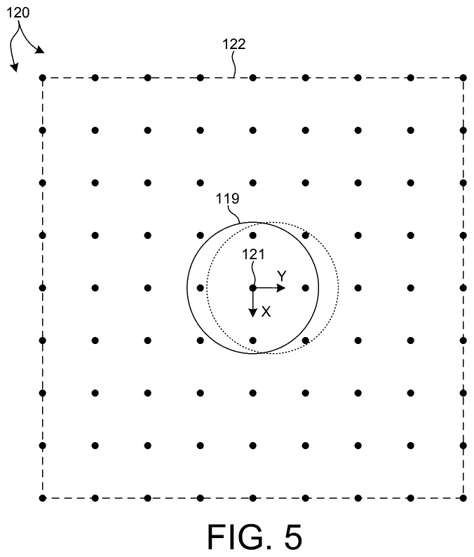

FIG. 5 is a top view of the workspace 120 of a specimen positioning system, e.g., wafer positioning system 110, in the X and Y directions. The dots represent sampling points within the workspace envelope 122. For example, dot 121 is the middle of the workspace. In the example movement, wafer 119 is translated in Y-direction.

In some examples, the minimization illustrated in FIG. 1 is performed on a data set that includes multiple sampling points in the workspace of a specimen positioning system, e.g., the sampling points depicted in FIG. 5. In some of these examples, a step and settle movement, e.g., the movement described with reference to FIG. 4A, is initiated from each sampling point within the workspace envelope 122.

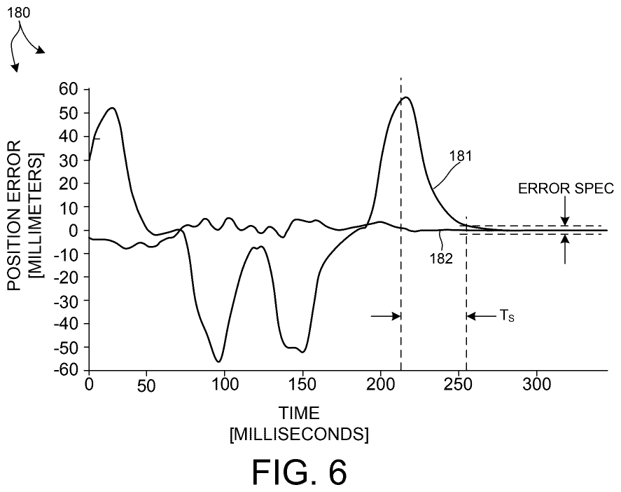

In some examples, the motion performance metric is settling time. FIG. 6 is a plot 180 illustrative of position error as a function of time during a move and settle movement in the Y-direction from a single sample point in the workspace of wafer positioning system 110. Plotline 181 illustrates position error during the move and settle movement before optimization of feedforward parameter values. Plotline 182 illustrates the position error during the move and settle movement after optimization of feedforward parameter values. As illustrated in FIG. 6, the settling time is the time elapsed from the moment the nominal movement, i.e., the commanded movement, is terminated, to the moment the position error settles within the required position error specification. In some other embodiments, the settling time is the time elapsed from the moment the nominal movement, i.e., the commanded movement, is initiated to the moment the position error settles within the required position error specification. The settling time, Tₛ, depicted in FIG. 6 is associated with the pre-determined movement before optimization of feedforward parameter values. As depicted in FIG. 6, the magnitude of the position error is much larger before optimization of feedforward parameter values. In addition, the settling time is much larger before optimization of feedforward parameter values. In general, the smaller the position error specification, the optimization of feedforward parameter values becomes more critical. In some embodiments, the position error specification is 50 nanometers or less. In these embodiments, the difference between settling time before and after optimization of feedforward parameter values is dramatic.

FIG. 1 illustrates a simplified schematic of an optical metrology or inspection system 160 positioned to inspect wafer 119 or perform measurements of structures formed on wafer 119. In some embodiments, system 160 is configured as a scanning system. In some other embodiments system 160 is configured as a point to point measurement system. In the depicted embodiment, wafer 119 is vacuum clamped to wafer chuck 120, while wafer chuck 120 is moved in multiple degrees of freedom by wafer positioning system 110.

As illustrated in FIG. 1, wafer 119 is illuminated by a normal incidence beam 163 generated by one or more illumination sources 161. Alternatively, the illumination subsystem may be configured to direct the beam of light to the specimen at an oblique angle of incidence. In some embodiments, system 160 may be configured to direct multiple beams of light to the specimen such as an oblique incidence beam of light and a normal incidence beam of light. The multiple beams of light may be directed to the specimen substantially simultaneously or sequentially.

Illumination source 161 may include, by way of example, a laser, a diode laser, a helium neon laser, an argon laser, a solid state laser, a diode pumped solid state (DPSS) laser, a xenon arc lamp, a gas discharging lamp, and LED array, or an incandescent lamp. The light source may be configured to emit near monochromatic light or broadband light. The illumination subsystem may also include one or more spectral filters that may limit the wavelength of the light directed to the specimen. The one or more spectral filters may be bandpass filters and/or edge filters and/or notch filters.

Normal incidence beam 163 is focused onto the substrate 110 by an objective lens 164. System 160 includes collection optics 162 to collect the light scattered and/or reflected by wafer 119 in response to the illumination light 163. Collection optics 162 focus the collected light onto a detector 165. The output signals 166 generated by detector 165 are supplied to a computing system 190 for processing the signals and determining the measurement parameter values 197 (e.g., material or structural properties, dimensions, presence of particles, etc.). System 160 is presented herein by way of non-limiting example, as wafer positioning system 110 may be implemented within many different electron based, x-ray based, or optical based metrology and inspection systems.

As illustrated in FIG. 1, the system 160 is configured as an inspection system or a metrology system. In this manner, the system may be configured to inspect or measure wafers and reticles used as part of a semiconductor manufacturing process. The methods and systems described herein are not limited to the inspection or measurement of semiconductor wafers or reticles, and may be applied to the inspection of other substrates that require accurate, high performance position control for processing.

As described hereinbefore, automatic tuning of feedforward control parameters is described with reference to motion control of wafer 119. However, in general, it is contemplated within the scope of this patent document that the methods and systems for automatic tuning of feedforward control parameters described herein may be applied to motion control of other specimens, including, but not limited to, semiconductor reticles, optical elements of a measurement system, such as lenses, detectors, polarizers, etc.

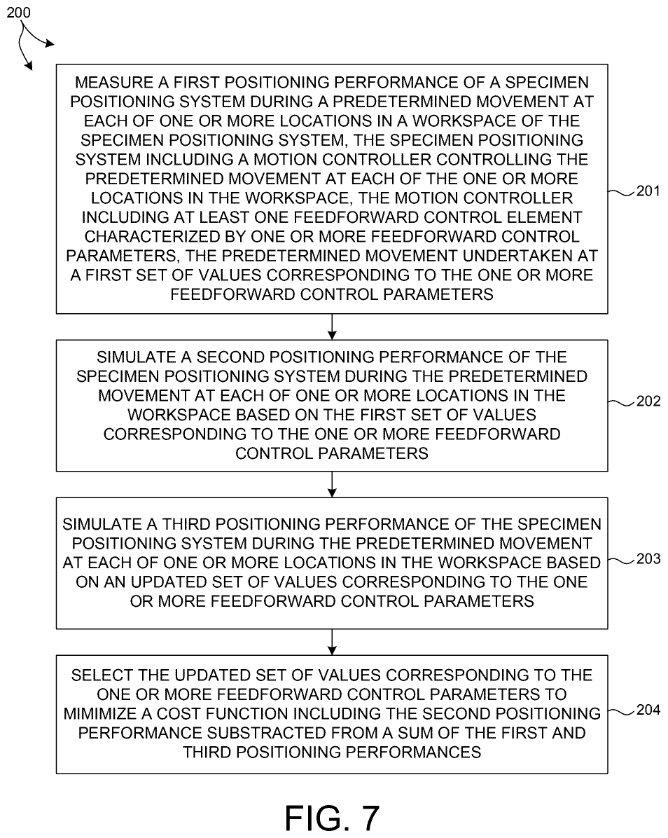

FIG. 7 illustrates a flowchart of an exemplary method 200 useful for automatically tuning feedforward control parameter values in several novel aspects. By way of non-limiting example, method 200 is described with reference to the measurement system 100 illustrated in FIG. 1 for explanatory purposes. Although, the description of system 100 includes references to specific hardware elements employed to achieve the elements of method 200, many other hardware elements known to persons of ordinary skill in the art may be contemplated to achieve an analogous result. Hence, any of the referenced hardware elements presented herein may be substituted, consolidated, modified, or eliminated without exceeding the scope of the description provided herein. Similarly, some of the elements of method 200 and the order of presentation of the elements of method 200 relate to the use of specific hardware elements described with reference to system 100. However, as many other hardware elements known to persons of ordinary skill in the art may be contemplated to achieve an analogous result, some of the method elements and the order of presentation of the method elements may be substituted, consolidated, modified, or eliminated without exceeding the scope of the description provided herein.

In block 201, a first positioning performance of a specimen positioning system is measured during a predetermined movement at each of one or more locations in a workspace of the specimen positioning system. The specimen positioning system including a motion controller controlling the predetermined movement at each of the one or more locations in the workspace. The motion controller includes at least one feedforward control element characterized by one or more feedforward control parameters. The predetermined movement undertaken at a first set of values corresponding to the one or more feedforward control parameters.

In block 202, a second positioning performance of the specimen positioning system is simulated during the predetermined movement at each of one or more locations in the workspace based on the first set of values corresponding to the one or more feedforward control parameters.

In block 203, a third positioning performance of the specimen positioning system is simulated during the predetermined movement at each of one or more locations in the workspace based on an updated set of values corresponding to the one or more feedforward control parameters.

In block 204, the updated set of values corresponding to the one or more feedforward control parameters is selected to minimize a cost function including the second positioning performance subtracted from a sum of the first and third positioning performances.

In a further embodiment, system 100 includes one or more computing systems 190 employed to perform measurements of actual device structures positioned in accordance with the methods described herein. The one or more computing systems 190 may be communicatively coupled to the wafer positioning system 110. In one aspect, the one or more computing systems 190 are configured to receive motion data associated with measurements of the motion of the specimen under measurement.

It should be recognized that one or more steps described throughout the present disclosure may be carried out by a single computer system 190 or, alternatively, a multiple computer system 190. Moreover, different subsystems of system 100 may include a computer system suitable for carrying out at least a portion of the steps described herein. Therefore, the aforementioned description should not be interpreted as a limitation on the present invention but merely an illustration.

In addition, the computer system 190 may be communicatively coupled to the wafer positioning system 110 in any manner known in the art. For example, the one or more computing systems 190 may be coupled to computing systems associated with the wafer positioning system. In another example, the wafer positioning system may be controlled directly by a single computer system coupled to computer system 190.

The computer system 190 of measurement system 100 may be configured to receive and/or acquire data or information from the subsystems of the system (e.g., detectors, wafer positioning system, and the like) by a transmission medium that may include wireline and/or wireless portions. In this manner, the transmission medium may serve as a data link between the computer system 190 and other subsystems of system 100 (e.g., memory on-board system 100, external memory, or other external systems). In this manner, the transmission medium may serve as a data link between the computer system 190 and other systems. For example, the computing system 190 may be configured to receive measurement data from a storage medium (i.e., memory 192 or an external memory) via a data link. For instance, motion measurement results obtained using the sensors of wafer positioning system 110 described herein may be stored in a permanent or semi-permanent memory device (e.g., memory 192 or an external memory). In this regard, the measurement results may be imported from on-board memory or from an external memory system. Moreover, the computer system 190 may send data to other systems via a transmission medium. For instance, control commands 196 or an estimated parameter value 197 determined by computer system 190 may be communicated and stored in an external memory. In this regard, measurement results may be exported to another system.

Computing system 190 may include, but is not limited to, a personal computer system, mainframe computer system, workstation, cloud based computing system, image computer, parallel processor, or any other device known in the art. In general, the term “computing system” may be broadly defined to encompass any device having one or more processors, which execute instructions from a memory medium.

Program instructions 194 implementing methods such as those described herein may be transmitted over a transmission medium such as a wire, cable, or wireless transmission link. For example, as illustrated in FIG. 1, program instructions 194 stored in memory 192 are transmitted to processor 191 over bus 193. Program instructions 194 are stored in a computer readable medium (e.g., memory 192). Exemplary computer-readable media include read-only memory, a random access memory, solid-state memory, a magnetic or optical memory, or a magnetic tape.

Various embodiments are described herein for a semiconductor processing system (e.g., an inspection system, a metrology system, a lithographic system, an etch system, etc.). The term “substrate” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as quartz. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A method comprising:
measuring a first positioning performance of a specimen positioning system during a predetermined movement at each of one or more locations in a workspace of the specimen positioning system, the specimen positioning system including a motion controller controlling the predetermined movement at each of the one or more locations in the workspace, the motion controller including at least one feedforward control element characterized by one or more feedforward control parameters, the predetermined movement undertaken at a first set of values corresponding to the one or more feedforward control parameters;
simulating a second positioning performance of the specimen positioning system during the predetermined movement at each of one or more locations in the workspace based on the first set of values corresponding to the one or more feedforward control parameters;
simulating a third positioning performance of the specimen positioning system during the predetermined movement at each of one or more locations in the workspace based on an updated set of values corresponding to the one or more feedforward control parameters; and
selecting the updated set of values corresponding to the one or more feedforward control parameters to minimize a cost function including the second positioning performance subtracted from a sum of the first and third positioning performances.

2. The method of claim 1, wherein the first, second and third positioning performances are positioning errors after a predetermined time after initiation of the predetermined movement.

3. The method of claim 1, wherein the first, second, and third positioning performances are positioning errors after a predetermined time after termination of the predetermined movement.

4. The method of claim 1, wherein the one or more locations in the workspace includes multiple, different locations in the workspace in a direction aligned with a first degree of freedom of the specimen positioning system.

5. The method of claim 4, wherein the one or more locations in the workspace includes multiple, different locations in the workspace in a direction perpendicular with the first degree of freedom.

6. The method of claim 1, wherein the workspace of the specimen positioning system includes at least two degrees of freedom.

7. The method of claim 1, further comprising:
measuring a fourth positioning performance of the specimen positioning system during the predetermined movement at each of one or more locations in the workspace of the specimen positioning system based on the updated set of values corresponding to the one or more feedforward control parameters.

8. A semiconductor measurement system, comprising:
a specimen positioning system comprising:
at least one motion stage configured to move a specimen within a range of locations in at least one degree of freedom, the range of locations comprising a workspace of the specimen positioning system;
a measurement subsystem including one or more sensors configured to measure a motion of the specimen;
a motion controller configured to control the motion of the specimen, the motion controller including at least one feedforward control element characterized by one or more feedforward control parameters; and
a computing system configured to:
measure a first positioning performance of the specimen positioning system during a predetermined movement at each of one or more locations in the workspace of the specimen positioning system, the motion controller controlling the predetermined movement at each of the one or more locations in the workspace, the predetermined movement undertaken at a first set of values corresponding to the one or more feedforward control parameters;
simulate a second positioning performance of the specimen positioning system during the predetermined movement at each of one or more locations in the workspace based on the first set of values corresponding to the one or more feedforward control parameters;
simulate a third positioning performance of the specimen positioning system during the predetermined movement at each of one or more locations in the workspace based on an updated set of values corresponding to the one or more feedforward control parameters; and
select the updated set of values corresponding to the one or more feedforward control parameters to minimize a cost function including the second positioning performance subtracted from a sum of the first and third positioning performances.

9. The semiconductor measurement system of claim 8, wherein the first, second and third positioning performances are positioning errors after a predetermined time after initiation of the predetermined movement.

10. The semiconductor measurement system of claim 8, wherein the first, second, and third positioning performances are positioning errors after a predetermined time after termination of the predetermined movement.

11. The semiconductor measurement system of claim 8, wherein the one or more locations in the workspace includes multiple, different locations in the workspace in a direction aligned with a first degree of freedom of the specimen positioning system.

12. The semiconductor measurement system of claim 11, wherein the one or more locations in the workspace includes multiple, different locations in the workspace in a direction perpendicular with the first degree of freedom.

13. The semiconductor measurement system of claim 8, wherein the workspace of the specimen positioning system includes at least two degrees of freedom.

14. The semiconductor measurement system of claim 8, further comprising:
measuring a fourth positioning performance of the specimen positioning system during the predetermined movement at each of one or more locations in the workspace of the specimen positioning system based on the updated set of values corresponding to the one or more feedforward control parameters.

15. A semiconductor measurement system, comprising:
a specimen positioning system comprising:
at least one motion stage configured to move a specimen within a range of locations in at least one degree of freedom, the range of locations comprising a workspace of the specimen positioning system;
a measurement subsystem including one or more sensors configured to measure a motion of the specimen;
a motion controller configured to control the motion of the specimen, the motion controller including at least one feedforward control element characterized by one or more feedforward control parameters; and
a non-transitory, computer-readable medium storing instructions that, when executed by one or more processors, causes the one or more processors to:
measure a first positioning performance of the specimen positioning system during a predetermined movement at each of one or more locations in the workspace of the specimen positioning system, the motion controller controlling the predetermined movement at each of the one or more locations in the workspace, the predetermined movement undertaken at a first set of values corresponding to the one or more feedforward control parameters;
simulate a second positioning performance of the specimen positioning system during the predetermined movement at each of one or more locations in the workspace based on the first set of values corresponding to the one or more feedforward control parameters;
simulate a third positioning performance of the specimen positioning system during the predetermined movement at each of one or more locations in the workspace based on an updated set of values corresponding to the one or more feedforward control parameters; and
select the updated set of values corresponding to the one or more feedforward control parameters to minimize a cost function including the second positioning performance subtracted from a sum of the first and third positioning performances.

16. The semiconductor measurement system of claim 15, wherein the first, second and third positioning performances are positioning errors after a predetermined time after initiation of the predetermined movement.

17. The semiconductor measurement system of claim 15, wherein the first, second, and third positioning performances are positioning errors after a predetermined time after termination of the predetermined movement.

18. The semiconductor measurement system of claim 15, wherein the one or more locations in the workspace includes multiple, different locations in the workspace in a direction aligned with a first degree of freedom of the specimen positioning system.

19. The semiconductor measurement system of claim 18, wherein the one or more locations in the workspace includes multiple, different locations in the workspace in a direction perpendicular with the first degree of freedom.

20. The semiconductor measurement system of claim 15, wherein the workspace of the specimen positioning system includes at least two degrees of freedom.
